(19) United States
(12) Patent Application Publication
(10) Pub. No.: US 2023/0130238 A1
(43) Pub. Date: Apr. 27, 2023

(54) OLED DISPLAY DEVICE AND METHOD OF MANUFACTURING THEREOF

(71) Applicant: WUHAN CHINA STAR OPTOELECTRONICS SEMICONDUCTOR DISPLAY TECHNOLOGY CO., LTD., Wuhan (CN)

(72) Inventor: Jie Zhang, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 17/047,389

(22) PCT Filed: May 26, 2020
(86) PCT No.: PCT/CN2020/092266

§ 371 Date: Oct. 14, 2020

(30) Foreign Application Priority Data
Apr. 1, 2020 (CN) 202010248094.X

(51) Int. Cl. H10K 59/38; H10K 59/80; H10K 59/12

(52) U.S. Cl. CPC H10K 59/38; H10K 59/1201; H10K 59/8792

(57) ABSTRACT

An OLED display device includes an array substrate, an OLED light-emitting layer disposed on the array substrate, a first inorganic layer disposed on the array substrate and completely covering the OLED light-emitting layer, a first inkjet printing layer disposed on the first inorganic layer, a color film layer disposed on the first inkjet printing layer, a second inkjet printing layer disposed on the color film layer, and a second inorganic layer disposed on the first inkjet printing layer.

### TECHNICAL FIELD

The present disclosure relates to a field of display technology, particularly to an organic light-emitting diode (OLED) display device and a method of manufacturing the display device.

### BACKGROUND

In order to properly apply display technology to an external high-brightness environment, a polarizer (POL) is currently attached to a module film layer as a solution. A conventional display device having the polarizer includes an array substrate, an electroluminescence element (EL), a thin film encapsulation layer (TFE), and a polarizer (POL) successively stacked. Although the polarizer (POL) can effectively reduce a reflectivity of a panel under strong light, nearly 58% of emitted light still will be lost. The polarizer is thick and brittle, which is not conducive to development of dynamic and bendable products. In order to develop dynamic and bendable products based on OLED technology, it is necessary to provide new materials, new technologies, and new processes to replace the polarizer.

### SUMMARY

An embodiment of present disclosure provides an OLED display device and a method of manufacturing the display device, which is able to ensure a uniform thickness of a color film, and a thickness of a display body is correspondingly reduce to satisfy requirements of flexible OLED display products.

An embodiment of the present disclosure provides an OLED display device including an array substrate having a plurality of thin film transistors, an OLED light-emitting layer disposed on the array substrate, a first inorganic layer disposed on the array substrate and completely covering the OLED light-emitting layer, a first inkjet printing layer disposed on the first inorganic layer, a color film layer disposed on the first inkjet printing layer, a second inkjet printing layer disposed on the color film layer, and a second inorganic layer disposed on the first inkjet printing layer. The color film layer includes a color filter layer and black matrices, the color filter layer includes a plurality of red color resists, a plurality of green color resists, and a plurality of blue color resists, and the black matrices are disposed between any two of the red color resists, the green color resists, and the blue color resists.

In the OLED display device provided in the present disclosure, the OLED light-emitting layer includes a red sub-light emitting layer, a green sub-light emitting layer, and a blue sub-light emitting layer. And the red sub-light emitting layer, the green sub-light emitting layer, and the blue sub-light emitting layer are all located at opening zones of the array substrate.

In the OLED display device provided in the present disclosure, a material of the first inorganic layer and the second inorganic layer is selected from any one of nitrogen silicide, silicon oxynitride and aluminum oxide.

In the OLED display device provided in the present disclosure, materials of the first inkjet printing layer and the second inkjet printing layer are both organic photopolymerizable materials.

An embodiment of the present disclosure provides an OLED display device including an array substrate having a plurality of thin film transistors, an OLED light-emitting layer disposed on the array substrate, a first inorganic layer disposed on the array substrate and completely covering the OLED light-emitting layer, a first inkjet printing layer disposed on the first inorganic layer, a color film layer disposed on the first inkjet printing layer, a second inkjet printing layer disposed on the color film layer, and a second inorganic layer disposed on the first inkjet printing layer.

In the OLED display device provided in the present disclosure, the OLED light-emitting layer includes a red sub-light emitting layer, a green sub-light emitting layer, and a blue sub-light emitting layer. And the red sub-light emitting layer, the green sub-light emitting layer, and the blue sub-light emitting layer are all located at opening zones of the array substrate.

In the OLED display device provided in the present disclosure, a material of the first inorganic layer and the second inorganic layer is selected from any one of nitrogen silicide, silicon oxynitride and aluminum oxide.

In the OLED display device provided in the present disclosure, materials of the first inkjet printing layer and the second inkjet printing layer are both organic photopolymerizable materials.

An embodiment of the present disclosure provides a method of manufacturing an OLED display device, the method includes the following steps:

S10, providing an array substrate, the array substrate including a plurality of thin film transistors, and defining the array substrate with a plurality of opening zones;

S20, forming an OLED light-emitting layer by vapor-depositing a plurality of electroluminescent devices at the opening zones;

S30, forming a first inorganic layer on the array substrate, the first inorganic layer completely covers the OLED light-emitting layer;

S40, forming a first inkjet printing layer on the first inorganic layer by inkjet printing;

S50, forming a color film layer on the first inkjet printing layer;

S60, forming a second inkjet printing layer on the color film layer by inkjet printing; and

S70, forming a second inorganic layer on the second inkjet printing layer.

In the method of manufacturing the OLED display device provided in the present disclosure, in the step S20, the OLED light-emitting layer includes the red sub-light emitting layer, the green sub-light emitting layer, and the blue sub-light emitting layer, the red sub-light emitting layer, the green sub-light emitting layer, and the blue sub-light emitting layer are all located at the opening zones of the array substrate.

In the method of manufacturing the OLED display device provided in the present disclosure, in the step S30, the first inorganic layer is formed on the array substrate by chemical vapor deposition, and a material of the first inorganic layer is selected from any one of nitrogen silicide, silicon oxynitride and aluminum oxide.

In the method of manufacturing the OLED display device provided in the present disclosure, the step S40 includes the following steps:

S401, coating an inkjet printing ink material on the first inorganic layer; and

S402, irradiating the inkjet printing ink material with ultraviolet light to cure the inkjet printing ink material to obtain the first inkjet printing layer, the inkjet printing ink material is an organic photopolymerizable material.

In the method of manufacturing the OLED display device provided in the present disclosure, in the step S50, the color film layer includes a color filter layer and black matrices, the color filter layer includes a plurality of red color resists, a plurality of green color resists, and a plurality of blue color resists, and the black matrices are disposed between any two of the red color resists, the green color resists, and the blue color resists.

Compared with the prior art, the embodiments of the present disclosure provide an OLED display device and a method of manufacturing the display device, the color film process is applied in the inkjet printing layer process, a uniform thickness of the color film is ensured in the manufacturing process, a thickness of the OLED display device is also reduced at the same time, such that the OLED display device satisfies a common need of flexible products.

### DESCRIPTION OF DRAWINGS

FIG. 1 is a cross-sectional structural schematic diagram of an OLED display device provided by an embodiment of the present disclosure.

FIG. 2 is a flow chart of a method of manufacturing an OLED display device provided by an embodiment of the present disclosure.

FIGS. 3A-3G are structural schematic diagrams of a method of manufacturing an OLED display device provided by an embodiment of the present disclosure.

### DETAILED DESCRIPTION OF PREFERRED EMBODIMENTS

In the current OLED display device, one of the main problems is that a polarizer is very thick and is made of brittle materials, which is not conducive to development of dynamic and bendable products, namely it is necessary to reduce the polarizer, which leads to increased reflectivity of the panel under strong light . The present disclosure provides an OLED display device having a new POL-less technology structure, that the OLED display includes a color filter that replaces the polarizer (POL), which is able to solve the above technical problems. The thickness of the functional layer is reduced from 100 µm to less than 5 µm, and a light output efficiency of the OLED display is increased from 42% to 60%. The detail about the specific implementation is described as follow.

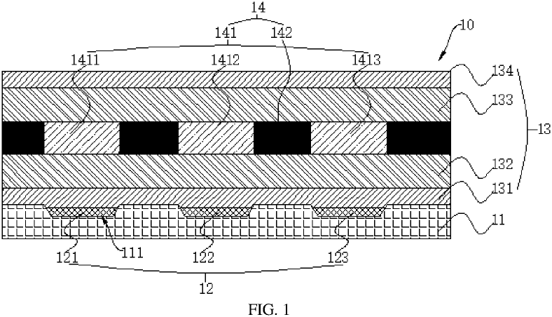

As shown, FIG. 1 is a cross-sectional structural schematic diagram of an OLED display device provided by an embodiment of the present disclosure. The OLED display device 10 includes an array substrate 11 having a plurality of thin film transistors (TFTs), an OLED light-emitting layer 12 disposed on the array substrate 11, a first inorganic layer 131 disposed on the array substrate 11 and completely covering the OLED light-emitting layer 12, a first inkjet printing layer 132 disposed on the first inorganic layer 131, a color film layer 14 disposed on the first inkjet printing layer 132, a second inkjet printing layer 133 disposed on the color film layer 14, and a second inorganic layer 134 disposed on the first inkjet printing layer 132.

Specifically, the color film layer 14 includes a color filter layer 141 and black matrices (BM) 142, the color filter layer 141 corresponds to the opening zones 111 on the array substrate 11, the black matrices 142 correspond to parts except the opening zones 111 on the array substrate 11. In one embodiment, a surface topography of the color filter layer 141 includes arc-shaped surfaces, convex surfaces, concave surfaces, or a combination thereof. The color film layer 14 is manufactured by a coating process method, which is able to ensure a uniform thickness of the color film in the process.

Specifically, the color filter layer 141 includes a plurality of red color resists 1411, a plurality of green color resists 1412, and a plurality of blue color resists 1413, and the black matrices 142 are disposed between any two of the red color resists 1411, the green color resists 1412, and the blue color resists 1413. The red color resists 1411, the green color resists 1412, and the blue color resists 1413 respectively correspond to the colors of a plurality of sub-pixels.

Specifically, the OLED light emitting layer 12 includes a red sub-light emitting layer 121, a green sub-light emitting layer 122, and a blue sub-light emitting layer 123; the red sub-light emitting layer 121, the green sub-light emitting layer 122, and the blue sub-light emitting layer 123 are all located at the opening zones 111 of the array substrate 11.

Specifically, the first inorganic layer 131, the first inkjet printing layer 132, the second inkjet printing layer 133, and the second inorganic layer 134 constitute a thin film encapsulation layer (TFE) 13 of the OLED display device 10. The color film layer 14 is located between the first inkjet printing layer 132 and the second inkjet printing layer 133.

In one embodiment, a material of the first inorganic layer 131 and the second inorganic layer 134 is selected from any one of nitrogen silicide (SiNx), silicon oxynitride (SiOxNy), and aluminum oxide (AlOx). A manufacturing method of the first inorganic layer 131 and the second inorganic layer 134 respectively include and are not limited to chemical vapor deposition (CVD), atomic layer deposition (ALD), and other processes.

In one embodiment, materials of the first inkjet printing layer 132 and the second inkjet printing layer 133 are both organic photopolymerizable materials. The thickness of the first inkjet printing layer 132 and the second inkjet printing layer 133 can be determined according to process conditions.

After the second inorganic layer 134 is deposited, the polarizer is then removed in a post-module assembly (MOD) process (driving IC and printed circuit board lamination process), thus obtaining the OLED display device 10.

In the embodiment of the present disclosure, the thickness of the OLED display device 10 is reduced by increasing the color film manufacturing process, reducing part of the polarizers, and applying the color film manufacturing process in the inkjet printing layer, such that the OLED display device satisfies a common need of flexible products.

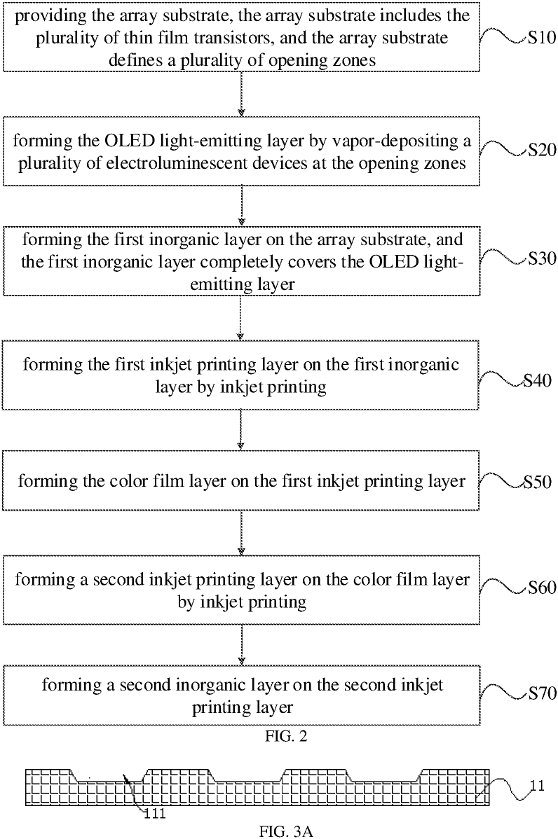

As shown, FIG. 2 is a flow chart of a manufacturing method of the OLED display device provided by an embodiment of the present disclosure. The method includes following steps:

S10, providing the array substrate 11, the array substrate 11 including the plurality of thin film transistors, and defining the array substrate 11 with the plurality of opening zones 111.

Specifically, the step S10 also includes:

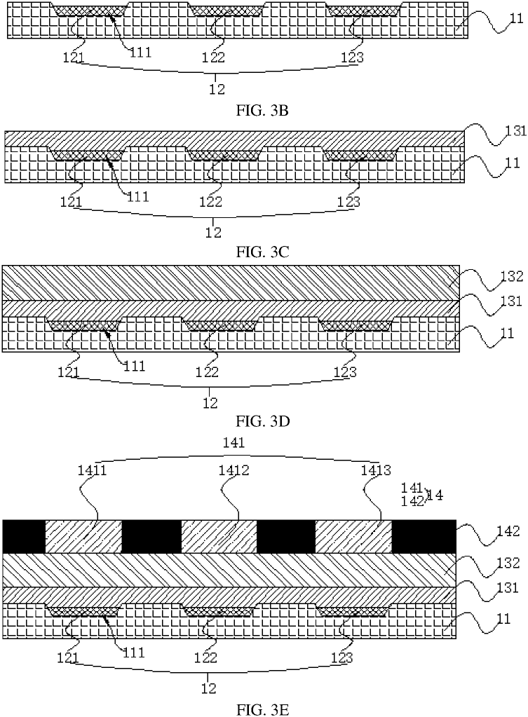

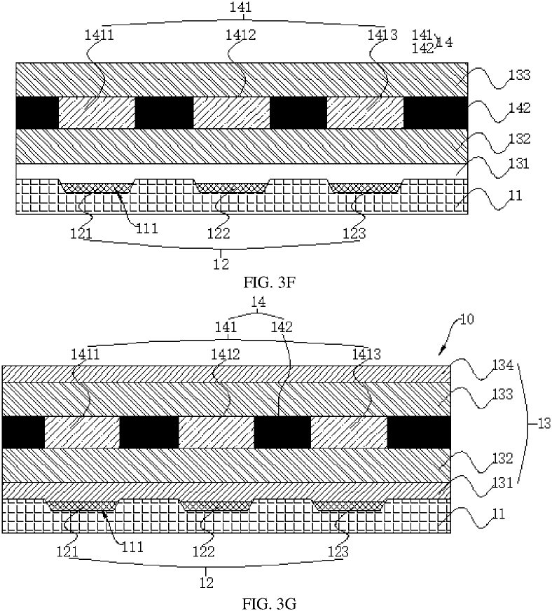

First, providing the array substrate 11, the array substrate 11 includes the plurality of thin film transistors, the array substrate 11 is defined with the plurality of opening zones 111. The thin film transistor includes a gate, a gate insulating layer, an inter-insulating layer, a source and drain, etc., and the thin film transistor may also include other conventional film layers, as shown in FIG. 3A.

S20, forming the OLED light-emitting layer 12 by vapor-depositing a plurality of electroluminescent devices at the opening zones 111.

Specifically, the step S20 also includes:

Forming the OLED light-emitting layer 12 by vapor-depositing the plurality of electroluminescent devices at the opening zones 111 of the array substrate 11. The OLED light-emitting layer 12 includes the red sub-light emitting layer 121, the green sub-light emitting layer 122, and the blue sub-light emitting layer 123; the red sub-light emitting layer 121, the green sub-light emitting layer 122, and the blue sub-light emitting layer 123 are all located at the opening zones 111 of the array substrate 11, as shown in FIG. 3B.

S30, forming the first inorganic layer 131 on the array substrate 11, and the first inorganic layer 131 completely covers the OLED light-emitting layer 12.

Specifically, the step S30 also includes:

Forming the first inorganic layer 131 on the array substrate 11 so that the first inorganic layer 131 completely covers the OLED light-emitting layer 12. The material of the first inorganic layer 131 is selected from any one of nitrogen silicide (SiNx), silicon oxynitride (SiOxNy), and aluminum oxide (AlOx). A manufacturing method of the first inorganic layer 131 includes and is not limited to chemical vapor deposition (CVD), atomic layer deposition (ALD), and other processes, as shown in FIG. 3C.

S40, forming the first inkjet printing layer 132 on the first inorganic layer 131 by inkjet printing.

Specifically, the step S40 also includes:

First, coating an inkjet printing ink material on the first inorganic layer 131, then irradiating the inkjet printing ink material with ultraviolet light to cure the inkjet printing ink material to obtain the first inkjet printing layer 132; wherein the inkjet printing ink material is an organic photopolymerizable material, and the thickness of the first inkjet printing layer 132 can be determined according to process conditions, as shown in FIG. 3D.

S50, forming the color film layer 14 on the first inkjet printing layer 132.

Specifically, the step S50 also includes:
S501, coating a light-shielding film on the first inkjet printing layer 132 and forming black matrices 142 corresponding to the gap position between two adjacent opening zones 111 after patterning; and
S502, forming a color filter layer 141 on the first inkjet printing layer 132 corresponding to the opening zones 111, wherein the black matrices 142 and the color filter layer 141 constitute the color film layer 14.

The color filter layer 141 includes a plurality of red color resists 1411, a plurality of green color resists 1412, and a plurality of blue color resists 1413, and the black matrices 142 are disposed between any two of the red color resists 1411, the green color resists 1412, and the blue color resists 1413, as shown in FIG. 3E.

Specifically, the S50 also includes:
S501, coating a color filter film on the first inkjet printing layer 132 corresponding to the opening zones 111, after patterning, forming a color filter layer 141 corresponding to the opening zones 111.
S502, forming a light-shielding film on the color filter layer 141 and forming black matrices 142 corresponding to the gap position between two adjacent opening zones 111 after patterning, wherein the black matrices 142 extend to the edge position of the color filter layer 141.

Specifically, the color filter layer 141 includes a plurality of red color resists 1411, a plurality of green color resists 1412, and a plurality of blue color resists 1413, and the black matrices 142 are disposed between any two of the red color resists 1411, the green color resists 1412, and the blue color resists 1413, as shown in FIG. 3E.

S60, forming a second inkjet printing layer 133 on the color film layer 14 by inkjet printing.

Specifically, the step S60 also includes:

First, coating an inkjet printing ink material on the color film layer 14, then irradiating the inkjet printing ink material with ultraviolet light to cure the inkjet printing ink material to obtain the second inkjet printing layer 133; wherein the inkjet printing ink material is an organic photopolymerizable material, and the thickness of the second inkjet printing layer 133 can be determined according to process conditions, as shown in FIG. 3F.

S70, forming a second inorganic layer 133 on the second inkjet printing layer 134.

Specifically, the step S70 also includes:

Forming the second inorganic layer 134 on the second inkjet printing layer 133, the material of the second inorganic layer 134 is selected from any one of silicon nitride (SiNx), silicon oxynitride (SiOxNy) and aluminum oxide (AlOx). A manufacturing method of the second inorganic layer 134 includes and is not limited to chemical vapor deposition (CVD), atomic layer deposition (ALD) and other processes. After the second inorganic layer 134 is deposited, the polarizer is then removed in a post-module assembly (MOD) process (driving IC and printed circuit board lamination process), thus obtaining the OLED display device 10, as shown in FIG. 3G.

The specific implementation of the above operations can refer to the previous embodiments, and will not be repeated here.

In summary, the embodiments of the present disclosure provide an OLED display device and a method of manufacturing the display device, the color film process is applied in the inkjet printing layer process, a uniform thickness of the color film is ensured in the manufacturing process, a thickness of the OLED display device is also reduced at the same time, such that the OLED display device satisfies a common need of flexible products.

It can be understood that for those of ordinary skill in the art, equivalent replacements or changes can be made according to the technical solutions and inventive concepts of the present disclosure, and all such changes or replacements should fall within the protection scope of the claims appended to the present disclosure.

What is claimed is:

1. An organic light-emitting diode (OLED) display device, comprising: an array substrate having a plurality of thin film transistors, an OLED light-emitting layer disposed on the array substrate, a first inorganic layer disposed on the array substrate and completely covering the OLED light-emitting layer, a first inkjet printing layer disposed on the first inorganic layer, a color film layer disposed on the first inkjet printing layer, a second inkjet printing layer disposed on the color film layer, and a second inorganic layer disposed on the first inkjet printing layer;
wherein the color film layer comprises a color filter layer and black matrices, the color filter layer comprises a plurality of red color resists, a plurality of green color resists, and a plurality of blue color resists, and the black matrices are disposed between any two of the red color resists, the green color resists, and the blue color resists.

2. The OLED display device of claim 1, wherein the OLED light-emitting layer comprises a red sub-light emitting layer, a green sub-light emitting layer, and a blue sub-light emitting layer, and the red sub-light emitting layer, the green sub-light emitting layer, and the blue sub-light emitting layer are all located at opening zones of the array substrate.

3. The OLED display device of claim 1, wherein a material of the first inorganic layer and the second inorganic layer is selected from any one of nitrogen silicide, silicon oxynitride and aluminum oxide.

4. The OLED display device of claim 1, wherein materials of the first inkjet printing layer and the second inkjet printing layer are both organic photopolymerizable materials.

5. An OLED display device, comprising: an array substrate having a plurality of thin film transistors, an OLED light-emitting layer disposed on the array substrate, a first inorganic layer disposed on the array substrate and completely covering the OLED light-emitting layer, a first inkjet printing layer disposed on the first inorganic layer, a color film layer disposed on the first inkjet printing layer, a second inkjet printing layer disposed on the color film layer, and a second inorganic layer disposed on the first inkjet printing layer.

6. The OLED display device of claim 1, wherein the OLED light-emitting layer comprises a red sub-light emitting layer, a green sub-light emitting layer, and a blue sub-light emitting layer, and the red sub-light emitting layer, the green sub-light emitting layer, and the blue sub-light emitting layer are all located at opening zones of the array substrate.

7. The OLED display device of claim 1, wherein a material of the first inorganic layer and the second inorganic layer is selected from any one of nitrogen silicide, silicon oxynitride and aluminum oxide.

8. The OLED display device of claim 1, wherein materials of the first inkjet printing layer and the second inkjet printing layer are both organic photopolymerizable materials.

9. A method of manufacturing an organic light-emitting diode (OLED) display device, wherein the method comprises following steps:
S10, providing an array substrate, the array substrate comprising a plurality of thin film transistors, and defining the array substrate with a plurality of opening zones;
S20, forming an OLED light emitting layer by vapor-depositing a plurality of electroluminescent devices at the opening zones;
S30, forming a first inorganic layer on the array substrate, wherein the first inorganic layer completely covers the OLED light-emitting layer;
S40, forming a first inkjet printing layer on the first inorganic layer by inkjet printing;
S50, forming a color film layer on the first inkjet printing layer;
S60, forming a second inkjet printing layer on the color film layer by inkjet printing; and
S70, forming a second inorganic layer on the second inkjet printing layer.

10. The method of manufacturing an OLED display device of claim 9, wherein in the step S20, the OLED light-emitting layer comprises a red sub-light emitting layer, a green sub-light emitting layer, and a blue sub-light emitting layer; wherein the red sub-light emitting layer, the green sub-light emitting layer, and the blue sub-light emitting layer are all located at the opening zones of the array substrate.

11. The method of manufacturing the OLED display device of claim 9, wherein in the step S30, the first inorganic layer is formed on the array substrate by chemical vapor deposition, and a material of the first inorganic layer is selected from any one of nitrogen silicide, silicon oxynitride, and aluminum oxide.

12. The method of manufacturing the OLED display device of claim 9, wherein the step S40 comprises following steps:
S401, coating an inkjet printing ink material on the first inorganic layer; and
S402, irradiating the inkjet printing ink material with ultraviolet light to cure the inkjet printing ink material to obtain the first inkjet printing layer, wherein the inkjet printing ink material is an organic photopolymerizable material.

13. The method of manufacturing the OLED display device of claim 9, wherein in the step S50, the color film layer comprises a color filter layer and black matrices, the color filter layer comprises a plurality of red color resists, a plurality of green color resists, and a plurality of blue color resists, and the black matrices are disposed between any two of the red color resists, the green color resists, and the blue color resists.
